(19) United States
(12) Patent Application Publication
(10) Pub. No.: US 2012/0137787 A1
(43) Pub. Date: Jun. 7, 2012

(54) PIEZOELECTRIC SENSOR AND A METHOD OF FABRICATING A PIEZOELECTRIC SENSOR

(76) Inventors: Kui Yao, Singapore (SG); Chin Yaw Tan, Singapore (SG); Ajit S. Gaunekar, Singapore (SG); Hon Yu Peter Ng, Singapore (SG)

(21) Appl. No.: 13/390,515

(22) PCT Filed: Aug. 13, 2010
(86) PCT No.: PCT/SG2010/000299

§ 371 Date: Feb. 14, 2012

Related U.S. Application Data
(60) Provisional application No. 61/233,944, filed on Aug. 14, 2009.

(51) Int. Cl. G01L 1/16; H01L 41/04; H01L 41/22

(52) U.S. Cl. 73/767; 29/25.35; 310/323.21

(57) ABSTRACT

A piezoelectric sensor comprising a piezoelectric film formed on a surface of an object to be monitored; a plurality of electrodes formed on a surface of the piezoelectric film; and wherein electrical polarization of the piezoelectric film is about coplanar with the surface of the piezoelectric film. A method of forming a piezoelectric sensor. The method comprises forming a piezoelectric film on a surface of an object to be monitored; forming electrodes on a surface of the piezoelectric film; and orientating electrical polarization in the piezoelectric film to be about coplanar with the surface of the piezoelectric film.

### TECHNICAL FIELD

This application relates to piezoelectric sensors and in particular, to a piezoelectric sensor made of piezoelectric film and a method of fabricating piezoelectric sensors.

### BACKGROUND

Condition monitoring is an important aspect in intelligent systems with self-diagnosing functions for upkeeping civic structures, vehicles and machinery arrangements. In many cases, without self-diagnosing functions, manual checking and maintenance efforts are time consuming and costly, and the losses arising from potential structural failure can be significantly higher than the cost of the parts to replaced. Real time condition monitoring can not only reduce the cost of routine manual checking and maintenance, it can also predict possible catastrophic failures in advance.

Monitoring of stress/strain or vibration is important in many applications, particularly for a machine with moving parts. Conventional strain sensors detect strain on the basis of resistance change, requiring an external power source and having a low response speed. Piezoelectric sensing is an alternative approach that is receiving much attention for condition monitoring applications. Piezoelectric strain sensors characteristically require little power to operate and, in principle, even require no external power source in principle. This makes them particularly attractive for continuous real-time condition monitoring. Piezoelectric strain sensors also have a significantly quicker response compared to conventional piezoresistive sensors.

State of the art piezoelectric sensors are typically fabricated and subsequently bonded or assembled on surfaces of objects to monitor strain or vibration in the object. Such sensors often do not conform easily to the surface, particularly when the surface is curved. As a result, strain in the object, which is typically very small, is often not effectively coupled to the piezoelectric material in the piezoelectric sensor.

In addition, it is difficult to produce a consistent bonding structure with a bonding agent when adhering a piezoelectric sensor to a surface of an object, thereby affecting strain coupling between the surface and the piezoelectric material significantly. Long term stability of the bonding structure, which is subjected to continuous movement, is also in question. The bonding method is therefore not ideal for handling thin and large piezoelectric layers.

Existing piezoelectric strain sensors are typically made of thin piezoelectric layers for effective coupling while minimizing any resultant clamping effect. Such piezoelectric thin layers used for strain sensors typically have two electrodes that sandwich the piezoelectric thin layer in between. In such sandwich electrode configurations, the polarization and electrical field generating the output signal are perpendicular to the electrodes and also perpendicular to surface of the object. However, the strain to be measured is usually in the plane of the surface of the object. This means that strain direction is not aligned with, but is instead perpendicular to the polarization and electrical field generating the output signal, resulting in the sensor utilizing a small piezoelectric voltage constant g₃₁. In addition, the direction of strain in the plane of the object cannot be determined. Voltage output, which is proportional to distance between the electrodes, is also limited by the small thickness of the piezoelectric layers.

### SUMMARY OF THE INVENTION

A novel piezoelectric strain sensor is provided which comprises a piezoelectric thin layer deposited and in-situ processed on the surface of the object to be monitored.

Ferroelectric polymer films are used as the piezoelectric materials, and are deposited on the surface of the object by solution coating methods, such as spin-coating, spray coating, and dip-coating. The film is subjected to a thermal treatment after deposition. An example of ferroelectric polymer film used is polyvinylidene fluoride (PVDF)-based polymer, such as the poly(vinylidene fluoride-trifluoroethylene) (P(VDF-TrFE)) copolymer.

A pair of interdigital electrodes is deposited on the top of the piezoelectric layer for strain monitoring, in which the polarization and the electrical signal output are arranged in about the same plane with the strain to be monitored.

Through use of the in-plane interdigital electrodes, the piezoelectric strain sensor, according to the present technology, can measure the strain along a specific direction by appropriately arranging the orientation of the electrodes. Alternatively, circular interdigital electrodes can be used to determine isotropic strain without necessarily specifying the direction.

The presently disclosed piezoelectric sensor allows strain measurement to be realized through the larger piezoelectric constant g₃₃, as opposed to g₃₁ in conventional piezoelectric strain sensors. It also removes voltage output constraint limited by small thickness of the piezoelectric layer. Hence, sensitivity of the strain measurement is improved.

The presently disclosed piezoelectric sensor also provides thin film strain sensing with improved sensitivity, reliability, durability and effectiveness for strain condition monitoring, since the piezoelectric thin film strain sensor is fabricated directly on the surface of the object to be monitored. In addition, the fabrication method of the thin film strain sensors is compatible with mass production, and can effectively produce consistent and durable piezoelectric strain sensors over a large area.

In addition, a piezoelectric sensor array can be provided comprising a plurality of sensors with different orientations and shapes which can be used to provide more comprehensive information for strain distribution analysis.

According to a first aspect, there is provided a piezoelectric sensor comprising a piezoelectric film formed on a surface of an object to be monitored; a plurality of electrodes formed on a surface of the piezoelectric film; and wherein electrical polarization of the piezoelectric film is about coplanar with the surface of the piezoelectric film.

The piezoelectric film may be formed on the surface of the object by a solution coating process.

The electrodes may comprise a pair of interdigital electrodes. The electrodes may comprise a pair of circular electrodes.

The electrodes may be formed on a surface of the piezoelectric film facing away from the object to be monitored.

An insulating layer may be disposed between the piezoelectric film and the surface of the object to be monitored. The insulating layer may be a silicon dioxide or a polymeric material.

The piezoelectric film may comprise a ferroelectric polymer. The piezoelectric film may have a thickness of less than or equal to 10 μm.

According to second aspect, there is provided a piezoelectric sensor array comprising a plurality of piezoelectric sensors as mentioned above, wherein electrodes of the plurality of piezoelectric sensors are placed at different orientations such that collective electrical output from the plurality of piezoelectric sensors determine strain distribution of the object.

According to a third aspect, there is provided a method of forming a piezoelectric sensor, the method comprising forming a piezoelectric film on a surface of an object to be monitored; forming electrodes on a surface of the piezoelectric film; and orientating electrical polarization in the piezoelectric film to be about coplanar with the surface of the piezoelectric film.

Forming the piezoelectric film may comprise coating a polymer on the object and thermally treating the coated polymer. The coating may be by solution coating selected from the group comprising dip-coating, spray-coating and spin-coating. The polymer may be a ferroelectric polymer.

Orientating the electrical polarization in the piezoelectric film may comprise applying an electric field through the electrodes to electrically pole the piezoelectric film after forming the piezoelectric film and the electrodes.

Forming the electrodes may comprise forming a pair of interdigital electrodes. This may include spacing the electrodes apart in a direction such that strain of the surface of the object along the direction can be detected with electrical output from the electrodes.

Alternatively, forming the electrodes may comprise forming a pair of circular interdigital electrodes. Forming the pair of circular interdigital electrodes may be configured for allowing isotropic strain coplanar with the surface of the object to be detected with electrical output from the electrodes.

Forming the electrodes may include patterning by a photolithographic process a conductive layer deposited on the piezoelectric film.

The method may further comprise forming an insulating layer on the surface of the object before forming the piezoelectric layer.

According to a fourth aspect, there is provided a method of forming a piezoelectric sensor array comprising forming a plurality of piezoelectric sensors as mentioned above, the method including forming electrodes of the plurality of piezoelectric sensors at different orientations such that collective electrical output from the plurality of piezoelectric sensors can determine strain distribution of the object.

### BRIEF DESCRIPTION OF THE DRAWINGS

FIG. 1 is a schematic diagram of an exemplary piezoelectric sensor with in-plane polarization for condition monitoring comprising a layer of P(VDF-TrFE) polymer piezoelectric thin film coated on a surface of a stainless steel part to be monitored;

FIG. 2 is a schematic diagram of an exemplary piezoelectric sensor array comprising a plurality of the piezoelectric sensors of FIG. 1, comprising a P(VDF-TrFE) piezoelectric thin film coated on a surface of a stainless steel part for strain condition monitoring and a plurality of interdigital electrodes with different orientations;

FIG. 3 is a schematic diagram of an exemplary piezoelectric sensor with circular interdigital electrodes, comprising a P(VDF-TrFE) piezoelectric thin film coated on a surface of a stainless steel part for strain condition monitoring;

FIG. 4 is a schematic diagram of an exemplary piezoelectric sensor with in-plane polarization comprising a P(VDF-TrFE) piezoelectric thin film directly coated on a surface of a glass part for strain condition monitoring;

FIG. 5 is a schematic diagram of a stainless steel flexure disc and an exemplary layout of interdigital electrodes of piezoelectric sensors superimposed on an outline of the flexure disc, with an inset of a close-up view of fine feature or fingers of the interdigital electrodes;

FIG. 6 is a micrograph of an exemplary pair of gold interdigital electrodes fabricated on a P(VDF-TrFE) film on a stainless steel flexure disc;

FIG. 7 is a photograph of a flexure disc with P(VDF-TrFE) thin film sensors assembled in a machine for condition monitoring;

FIG. 8 is a graph of voltage output of an P(VDF-TrFE) sensor with interdigital electrodes on a flexure beam of the flexure disc of FIG. 7 versus displacement of a central shaft of the flexure disc of FIG. 7, at different frequencies;

FIG. 9 is a graph of voltage output of a P(VDF-TrFE) sensor with top-bottom electrodes on the flexure beam of the flexure disc of FIG. 7 versus the displacement of the central shaft of the flexure disc of FIG. 7, at different frequencies;

FIG. 10 is a graph of voltage output of the P(VDF-TrFE) sensor of FIG. 8 in response to the displacement of the central shaft in time domain; and

FIG. 11 is an exemplary method of forming a piezoelectric sensor.

### DETAILED DESCRIPTION

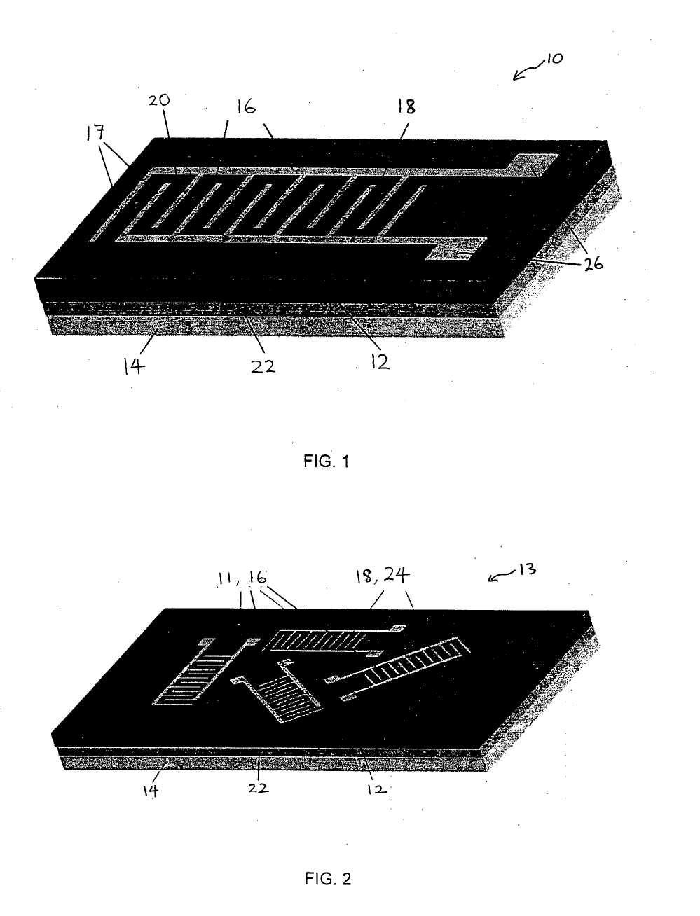

A piezoelectric sensor 10 and a method 100 of fabricating the piezoelectric sensor 10 are described below with reference to FIGS. 1 to 7 and FIG. 11.

The piezoelectric sensor 10 comprises a piezoelectric film 12 formed on a surface of an object or part 14 to be monitored, 102. A plurality of electrodes 16 is deposited on one side of the piezoelectric film 12, 104. The electrodes 16 are preferably parallel to each other and oriented such that electrical polarization (indicated by arrows 18) of the piezoelectric film 12 is about parallel with a plane of a surface 20 of the piezoelectric film 12 between the electrodes 16, i.e., the electrical polarization 18 is coplanar with the surface 20.

An example of a piezoelectric film 12 is a ferroelectric polymer such as a polyvinylidene fluoride (PVDF)-based polymer. An insulating layer 22 may be present in between the piezoelectric film 12 and the surface of the object or part 14 to be monitored.

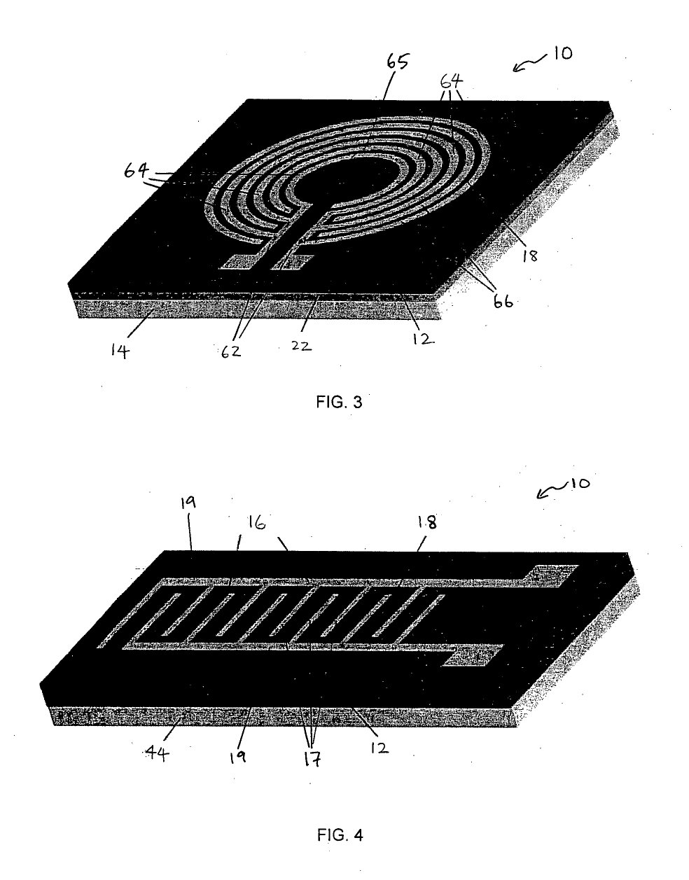

Examples of electrodes 16 include rectilinear interdigital electrodes 16 as shown in FIG. 4 and circular interdigital electrodes 66 as shown in FIG. 3.

The rectilinear interdigital electrodes 16 preferably comprise two electrodes 16 each having an arm 19 and a plurality of fingers 17 extending perpendicularly from the arm 19. The arms 19 are preferably arranged parallel to each other 19. Fingers 17 of the two electrodes 16 interdigitate, preferably parallel to each other 17.

The circular interdigital electrodes 16 preferably comprise two electrodes 66 each having a stem 62 and circular fingers 64 extending from the stem 62. The stems 62 are preferably straight and arranged parallel to each other 62. The circular fingers 64 of both electrodes 66 interdigitate preferably concentrically about a virtual centre 65.

A piezoelectric sensor array 13 as shown in FIG. 2 comprises a plurality of piezoelectric sensors 11 formed on a surface of an object or part 14 to be monitored. Each piezoelectric sensor 11 comprises a set of electrodes 16. The sets of electrodes 16 are placed at different orientations 24 to achieve differently oriented polarizations 18. In this way, collective electrical output from the electrodes 16 of the multiple sensors 11 can determine the strain distribution on the object or part 14.

Directly integrating a piezoelectric film on the surface of a machine or machine part is a very effective approach to realize real-time monitoring for its structural health condition, including strain (stress), delamination, crack, and vibration. Considering that the majority of machines or machine parts are made of a base metal/alloy, composite, or plastic, which cannot sustain a high annealing temperature, a poly(vinylidene fluoride) (PVDF)-based ferroelectric polymer is selected as an example of a piezoelectric material 12 to be deposited on the surface of a stainless steel part 14 at low temperature, and piezoelectric sensors 10, 11 are produced directly on the surface of the stainless steel part 14 for condition monitoring purpose.

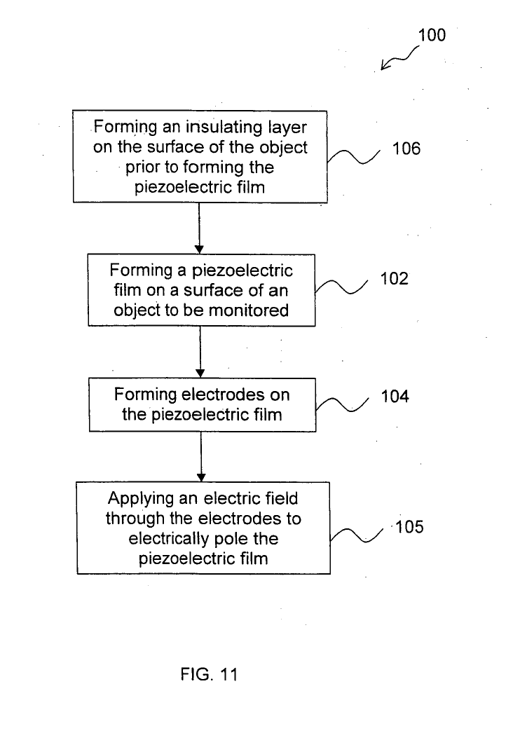

The method 100 in FIG. 11 comprises forming a piezoelectric film 12 on a surface of the object 14, 102. The piezoelectric film 12 may be formed by a solution coating process using a solution coating deposition method, such as dip-coating, spray coating, and spin-coating so as to provide a thin and uniformly conforming layer of the piezoelectric material 12 on the surface of the object 14. The method 100 further comprises forming a plurality of electrodes 16 on a surface 20 of the piezoelectric film 12, 104, such that electrical polarization in the piezoelectric layer 12 is about parallel with the plane of the surface 20 of the piezoelectric film 12. This is achieved by applying an electric field through the electrodes at an elevated temperature to electrically pole the piezoelectric film 105. The electrodes 16 may be formed using patterning techniques such as, but not limited to, photolithography, nanoimprint lithography, and various printing technologies. The plurality of electrodes 16 may be formed on the piezoelectric film 12, 104 either before or after deposition of the piezoelectric film 12 on the object 14, 102. An insulating layer 22 may be formed on a surface of the object 14 to be monitored 106 prior to forming the piezoelectric film 12 on the insulating layer 22 on the object 14, 102. The insulating layer 22 enables the poling process 105 to be carried out successfully with polarization about parallel with the surface plane and enables the piezoelectric sensor 10 to function properly when the object 14 is conductive.

FIG. 1 presents an exemplary piezoelectric sensor 10 comprising a poly(vinylidene fluoride-trifluoroethylene) (P(VDF-TrFE)) copolymer piezoelectric thin film 12 coated on the surface of a stainless steel part 14 to be monitored. An insulating layer 22 of silicon dioxide (SiO₂) film 22 with a thickness of 2.0 μm is first deposited on the surface of the stainless steel part 14, 106, by a plasma-enhanced chemical vapor deposition (PECVD) method. Then, a layer of P(VDF-TrFE) of about 10 μm in thickness is deposited on top of the SiO₂ film 22 on the stainless steel part 14, 102 by a solution dip-coating process. The solution for the coating of P(VDF-TrFE) is prepared by dissolving P(VDF-TrFE) particles in a mixture solvent of acetone and N,Ndimethylformamide (DMF). In one example, the mixture solvent may have a composition of 50:50 in volume while the concentration of the P(VDF-TrFE) solution is 15% by weight. The P(VDF-TrFE) layer can also be deposited by many other solvent casting methods, such as spin coating and spray coating. The wet P(VDF-TrFE) layer as deposited is then dried at 80° C. for 10 minutes and then thermally treated by annealing at 135° C. to form the piezoelectric film 12. Annealing may take place for between 2 to 20 hours, for example.

Gold electrodes 16 are then formed on the piezoelectric film 12, 104. A layer of gold of 300 nm in thickness is deposited on the top surface 20 of the P(VDF-TrFE) film 12 by sputtering or evaporation deposition process. Other types of electrical conductors including aluminum can also be used as alternatives for the gold layer. The gold layer is patterned to form the pair of interdigital electrodes 16 as showed in FIG. 1 by a conventional photolithography process followed by wet etching of Au. The gap between two adjacent fingers 17 of the interdigital electrodes 16 is preferably 5 to 15 μm.

An electrical field of 750 to 1000 kV/cm is then applied between the two terminals of the interdigital electrodes 16 on the P(VDF-TrFE) film 12, 105 to electrically pole the ferroelectric P(VDF-TrFE) film by orientating the electrical polarization 18 to be aligned about in-parallel with the plane of the film surface 20. In one example, the electrical field may be applied at an elevated temperature of 100° C. for 4 minutes. After the poling electrical field is withdrawn, net polarization 18 in the P(VDF-TrFE) film 12 is aligned to be coplanar with the surface 20 of the film 12, as illustrated in FIG. 1.

Thus, any strain occurring at the surface of the stainless steel part 14 in the plane of the surface 20 can be effectively coupled to the P(VDF-TrFE) layer 12 as the P(VDF-TrFE) layer 12 is well conformed to the surface of the stainless steel part 14. The strain in the P(VDF-TrFE) layer 12 can generate an electrical signal through the piezoelectric effect at the two electrode terminals 26. For the P(VDF-TrFE) piezoelectric material 12, the electrical output is largely determined by the tensile or compressive strain in the direction of the polarization 18. In another words, the piezoelectric sensor 10 comprising the in-plane poled P(VDFTrFE) film 12 and the interdigital electrodes 16 are most sensitive to the strain in the direction of the electrical polarization 18, i.e., the direction 18 perpendicular to the electrode fingers 17.

To obtain more comprehensive information to analyze the strain in the stainless steel part 14, a plurality of interdigital electrodes 16 with different orientations 24, as showed in FIG. 2, can be deposited on top of the P(VDF-TrFE) film 12. By analyzing the outputs from the different sets 11 of the electrodes 16, both the magnitude and direction of the strain in the stainless steel part 14 can be determined.

In some cases, radial strain occurs in the stainless steel part 14, or only the in-plane strain magnitude is essential but not the direction. Thus, circular interdigital electrodes 16 can be used, as shown in FIG. 3, in which the P(VDF-TrFE) film 12 is poled in the radial direction 18 and the sensor 10 has a good response to the in-plane strain but does not tell the strain direction as it may not be required.

Many other materials can be used as the insulating layer 22, as an alternative to the SiO₂ film described above. One example is a polymer coating of polyvinyl alcohol (PVA). To prepare the PVA coating, PVA powder is first dissolved in water at 80° C., and then the PVA solution is spin-coated or dip-coated on the stainless steel part to act as the insulation layer 22 between the P(VDF-TrFE) layer 12 and the stainless steel part 14. In one embodiment, the thickness of the PVA layer may be around 2.0 μm.

FIG. 4 shows another embodiment of the piezoelectric sensor 10 with the piezoelectric layer 12 deposited on a surface of an insulating part 44, glass in this example. In this case, the piezoelectric P(VDF-TrFE) film 12 is deposited directly on the surface of the glass part 44 of which strain is to be monitored, without any other intermediate layer in between.

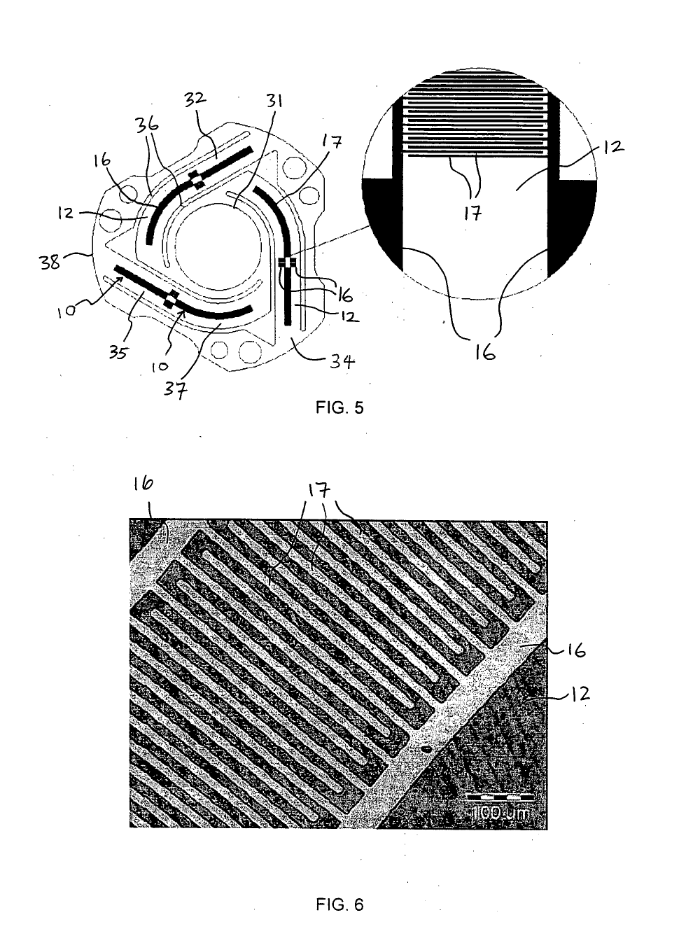

As shown in FIG. 5, piezoelectric sensors 10 as described above were applied to monitor the strain and vibration of an actual stainless steel machine part 34. The exemplary component 34 chosen for overlay with the strain sensors 10 was a flexure bearing disc 34 as shown in FIG. 5. The flexure bearing disc 34 was a flat disc made of stainless steel, having three pairs of slots 36 giving three separate beams 32. Each beam 32 had a shape which was a combination of a straight portion 35 and a circular arc portion 37. During the operation of the flexure disc 34, the central portion 31 was axially movable with a limited axial stiffness and the periphery 38 was fixed. Strain was thus generated in the flexure disc 14 when the central portion 31 was driven by an actuator (not shown). The strain distribution on each of the beams 32 was mainly due to a combination of bending and twisting of the beams 32 when the central portion 31 was displaced through a small distance.

P(VDF-TrFE) sensors 10 were fabricated directly on the surface of the stainless steel flexure discs 34 as described above. The first step of the fabrication process began with the deposition of an insulating layer (not shown) on the flexure disc: A 2 μm-thick silicon dioxide layer, deposited by PECVD, was selected as the insulating layer. For comparison purposes, sensors (not shown) with top-bottom electrode design were also fabricated, in which a 300 nm-thick aluminum layer was deposited by e-beam evaporation on the insulating silicon dioxide layer as the bottom electrode.

A layer of approximately 10 μm-thick P(VDF-TrFE) copolymer 12 was subsequently deposited on the flexure disc 34 by dip-coating the disc with the P(VDF-TrFE) solution, followed by thermal treatment by annealing at 135° C., as described above. Then a layer of 300 nm-thick gold was deposited to form electrodes 16 on the top of the P(VDF-TrFE) layer 12 by sputtering, and patterned by photolithography followed by gold chemical etching. FIG. 5 also shows the layout of the interdigital electrodes 16 superimposed on the outline of the stainless flexure disc 34. The inset shows a close-up view of the fine features or fingers 17 of the interdigital electrodes 16.

FIG. 6 presents a micrograph of a pair of gold interdigital electrodes 16 as fabricated on the P(VDF-TrFE) layer 12 on the stainless steel fixture disc 34.

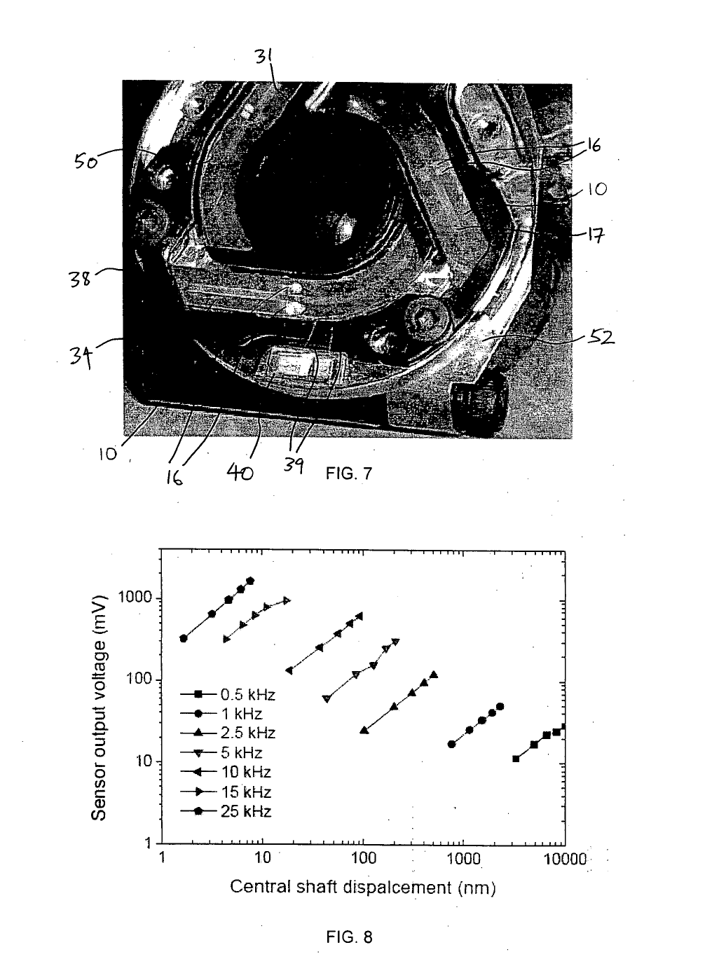

FIG. 7 shows the flexure disc 34 with the P(VDF-TrFE) sensors 10 assembled on a machine 52, in which the peripheral rim 38 is fully constrained while the central axis 31 can be moved by an actuator. Gold wires 39 were connected to the gold mounting pads of the electrodes 16 and wire bonded to a printed circuit board (PCB) 40 for measurement.

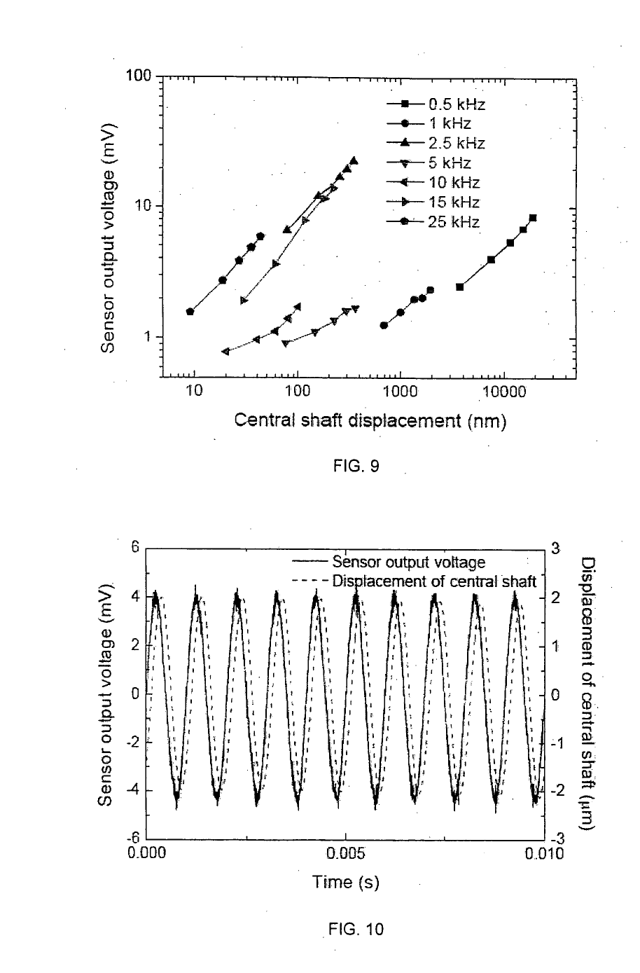

FIGS. 8 and 9 present the voltage output versus the displacement of the central shaft 31 at different frequencies for the P(VDF-TrFE) sensors 10 with interdigital electrodes 16 and the P(VDF-TrFE) sensors with top-bottom electrodes (not shown), respectively. The displacement of the central shaft 31 at different frequencies was determined with a laser scanning vibrometer. The results showed that the voltage output for all the P(VDF-TrFE) sensors increased with displacement of the central shaft and hence the resulting strain of the flexural disc 34. However, the P(VDF-TrFE) sensors 10 with the interdigital electrodes 16 exhibited significantly enhanced output voltage magnitude than those with the top-bottom electrodes, which was consistent with theoretical analysis results. In addition, the voltage output of the P(VDF-TrFE) sensors 10 also consistently increased with increasing frequency, whereas no consistent relationship could be identified for the sensors with the top-bottom electrodes. Further studies have uncovered that higher-order harmonic vibrations in the flexure beams 32 were excited with increasing the frequency, which could result in larger local strain and thus the enhanced output of the piezoelectric sensors 10 at higher frequency. The voltage output of the P(VDF-TrFE) sensors 10 with interdigital electrodes 16 in response to the displacement of the central shaft 31 in time domain is also presented in FIG. 10.

These testing results thus indicated that the output signals of the piezoelectric sensors 10 well reflected the actual vibration magnitude and the strain condition of the flexure discs 34.

Whilst there has been described in the foregoing description preferred embodiments of the present invention, it will be understood by those skilled in the technology concerned that many variations or modifications in details of design or construction may be made without departing from the present invention. For example, the electrodes 16 may be formed on a surface of the piezoelectric film facing the part to be monitored.

1. A piezoelectric sensor comprising:
a piezoelectric film formed on a surface of an object to be monitored;
a plurality of electrodes formed on a surface of the piezoelectric film; and wherein electrical polarization of the piezoelectric film is about coplanar with the surface of the piezoelectric film.

2. A piezoelectric sensor as claimed in claim 1, wherein the piezoelectric film is formed on the surface of the object by a solution coating process.

3. A piezoelectric sensor as claimed in claim 1, wherein the electrodes comprise a pair of interdigital electrodes.

4. A piezoelectric sensor as claimed in claim 1, wherein the electrodes comprise a pair of circular electrodes.

5. A piezoelectric sensor as claimed in claim 1, wherein the electrodes are formed on a surface of the piezoelectric film facing away from the object to be monitored.

6. A piezoelectric sensor as claimed in claim 1, wherein an insulating layer is disposed between the piezoelectric film and the surface of the object to be monitored.

7. A piezoelectric sensor as claimed in claim 6, wherein the insulating layer is a silicon dioxide.

8. A piezoelectric sensor as claimed in claim 6, wherein the insulating layer is of a polymeric material.

9. A piezoelectric sensor as described in claim 1, wherein the piezoelectric film comprises a ferroelectric polymer.

10. A piezoelectric sensor as claimed in claim 1, wherein the piezoelectric film has a thickness of less than or equal to 10 μm.

11. A piezoelectric sensor array comprising a plurality of piezoelectric sensors as claimed in claim 1, wherein electrodes of the plurality of piezoelectric sensors are placed at different orientations such that collective electrical output from the plurality of piezoelectric sensors determine strain distribution of the object.

12. A method of forming a piezoelectric sensor, the method comprising:
forming a piezoelectric film on a surface of an object to be monitored;
forming electrodes on a surface of the piezoelectric film; and
orientating electrical polarization in the piezoelectric film to be about coplanar with the surface of the piezoelectric film.

13. The method as claimed in claim 12, wherein forming the piezoelectric film comprises coating a polymer on the object and thermally treating the coated polymer.

14. The method as claimed in claim 13, wherein the coating is by solution coating selected from the group comprising dip-coating, spray-coating and spin-coating.

15. A method as claimed in claim 13, wherein the polymer is a ferroelectric polymer.

16. A method as claimed in claim 12, wherein orientating the electrical polarization in the piezoelectric film comprises applying an electric field through the electrodes to electrically pole the piezoelectric film after forming the piezoelectric film and the electrodes.

17. A method as claimed in claim 12, wherein forming the electrodes comprises forming a pair of interdigital electrodes.

18. A method as claimed in claim 17, wherein forming the pair of interdigital electrodes includes spacing the electrodes apart in a direction such that strain of the surface of the object along the direction can be detected with electrical output from the electrodes.

19. A method as claimed in claim 12, wherein forming the electrodes comprises forming a pair of circular interdigital electrodes.

20. A method as claimed in claim 19 wherein forming the pair of circular interdigital electrodes is configured for allowing isotropic strain coplanar with the surface of the object to be detected with electrical output from the electrodes.

21. A method as claimed in claim 12, wherein forming the electrodes includes patterning by a photolithographic process a conductive layer deposited on the piezoelectric film.

22. A method as claimed in claim 12, further comprising forming an insulating layer on the surface of the object before forming the piezoelectric layer.

23. A method of forming a piezoelectric sensor array comprising forming a plurality of piezoelectric sensors, wherein each piezoelectric sensor is formed by forming a piezoelectric film on a surface of an object to be monitored; forming electrodes on a surface of the piezoelectric film; and orientating electrical polarization in the piezoelectric film to be about coplanar with the surface of the piezoelectric film, the method comprising forming electrodes of the plurality of piezoelectric sensors at different orientations such that collective electrical output from the plurality of piezoelectric sensors can determine strain distribution of the object.
